(19) United States
(12) Patent Application Publication
(10) Pub. No.: US 2013/0171570 A1
(43) Pub. Date: Jul. 4, 2013

(54) DRAWING APPARATUS, AND METHOD OF MANUFACTURING ARTICLE

(71) Applicant: CANON KABUSHIKI KAISHA, Tokyo (JP)

(72) Inventors: Koichi Sentoku, Kawachi-gun (JP); Hideki Ina, Tokyo (JP); Wataru Yamaguchi, Utsunomiya-shi (JP); Nobushige Korenaga, Utsunomiya-shi (JP)

(73) Assignee: CANON KABUSHIKI KAISHA, Tokyo (JP)

(21) Appl. No.: 13/721,540

(22) Filed: Dec. 20, 2012

(30) Foreign Application Priority Data
Dec. 28, 2011 (JP) 2011-289888

(51) Int. Cl. G21K 5/08; G03F 7/20

(52) U.S. Cl. CPC G21K 5/08; G03F 7/20
USPC 430/296; 250/453.11; 250/393; 250/216

(57) ABSTRACT

The present invention provides a drawing apparatus including a stage having a reference mark, and configured to hold a substrate and to be moved, a charged particle optical system, a first measuring device having an optical axis spaced apart from an axis of the charged particle optical system by a first distance and configured to measure a position of an alignment mark formed on the substrate, a second measuring device having an optical axis spaced apart from the axis of the charged particle optical system by a second distance and configured to measure a position of the reference mark, and a processor configured to obtain a baseline of the first measuring device based on positions of the reference mark respectively measured by the first measuring device and the second measuring device.

### BACKGROUND OF THE INVENTION

1. Field of the Invention

The present invention relates to a drawing apparatus, and a method of manufacturing an article.

2. Description of the Related Art

As a lithography apparatus for manufacturing a semiconductor device or the like, an exposure apparatus that projects a pattern of a reticle on a substrate (wafer) or a charged particle beam drawing apparatus that performs drawing on a substrate using a charged particle beam is used. In the lithography apparatus, positioning of a substrate (substrate alignment) is performed to maintain a high overlay accuracy.

As shown in FIG. 10, substrate alignment in the exposure apparatus is performed using an off-axis alignment scope OAS arranged apart from an optical axis AX_{PL} of a projection optical system PL. The distance on the substrate between an optical axis AX_{OAS} of the alignment scope OAS and the optical axis AX_{PL} of the projection optical system PL is called a baseline BL. The baseline BL is periodically measured. The measurement result is reflected to enable highly accurate substrate alignment.

When measuring the baseline BL, the position of the optical axis AX_{PL} of the projection optical system PL is detected using a detection system DS that implements TTR (Through The Reticle) and TTL (Through The Lens). More specifically, the detection system DS detects the position of the optical axis AX_{PL} of the projection optical system PL by observing the relative positions of reference marks RM1 and RM2 on a reticle R and reference marks M1 on a substrate stage ST whose images are formed via the projection optical system PL. The detection system DS needs to use light of a wavelength that causes no aberration even when passing through the projection optical system PL, and uses, for example, light having the same wavelength as that of exposure light.

When measuring the baseline BL, first, the alignment scope OAS detects a reference mark M0 on the substrate stage ST. The substrate stage ST is driven to locate the reference marks M1 under the projection optical system PL. The detection system DS detects the position of the optical axis AX_{PL} of the projection optical system PL, thereby obtaining the baseline BL.

The charged particle beam drawing apparatus cannot use the detection system DS that implements TTR and TTL (that is, form an equivalent detection system), although the alignment scope OAS can be used as an optical system for substrate alignment. This is because the charged particle beam drawing apparatus uses neither a reticle nor a mask (that is, maskless lithography).

Japanese Patent Laid-Open No. 2000-133566 has proposed a technique of implementing substrate alignment (particularly, baseline measurement) in a charged particle beam drawing apparatus. Japanese Patent Laid-Open No. 2000-133566 discloses a technique concerning baseline measurement by a measurement system using a charged particle beam.

However, in the conventional substrate alignment and, in particular, baseline measurement in the charged particle beam drawing apparatus, it is difficult to meet the measurement accuracy required of the recent charged particle beam drawing apparatus. One reason for this is that the S/N ratio of the signal measured using a charged particle beam is not high. To improve the measurement accuracy, the measurement may be performed a plurality of times. However, this leads to a longer measurement time and lower throughput.

### SUMMARY OF THE INVENTION

The present invention provides, for example, a drawing apparatus advantageous in measuring a baseline of a measuring device that measures an alignment mark.

According to one aspect of the present invention, there is provided a drawing apparatus for performing drawing on a substrate with a charged particle beam, including a stage having a reference mark, and configured to hold the substrate and to be moved, a charged particle optical system configured to emit the charged particle beam to the substrate, a first measuring device having an optical axis spaced apart from an axis of the charged particle optical system by a first distance and configured to measure a position of an alignment mark formed on the substrate, a second measuring device having an optical axis spaced apart from the axis of the charged particle optical system by a second distance shorter than the first distance and configured to measure a position of the reference mark, and a processor configured to obtain a baseline of the first measuring device based on positions of the reference mark respectively measured by the first measuring device and the second measuring device via movement of the stage, and a baseline of the second measuring device.

Further aspects of the present invention will become apparent from the following description of exemplary embodiments with reference to the attached drawings.

### BRIEF DESCRIPTION OF THE DRAWINGS

FIGS. 1A and 1B are views showing the arrangement of a drawing apparatus according to one embodiment of the present invention.

FIG. 2 is a view for explaining an example (secondary electron detector) of an obtaining unit that obtains the position of the optical axis of a charged particle optical system.

FIG. 3 is a view for explaining another example (Faraday cup) of the obtaining unit that obtains the position of the optical axis of the charged particle optical system.

FIG. 4 is a graph showing an example of a signal obtained by the Faraday cup.

FIGS. 5A and 5B are views showing the arrangement of a drawing apparatus according to the embodiment of the present invention.

FIG. 6 is a view showing the arrangement relationship between first measuring devices and second measuring devices in the drawing apparatus shown in FIGS. 5A and 5B.

FIG. 7 is a view showing an example of the arrangement relationship between the first measuring device and the second measuring device.

FIG. 8 is a view showing another example of the arrangement relationship between the first measuring device and the second measuring device.

FIG. 9 is a view for explaining detection of the position of the optical axis of a charged particle optical system in a multi-charged particle beam drawing apparatus.

FIG. 10 is a view for explaining substrate alignment in an exposure apparatus.

### DESCRIPTION OF THE EMBODIMENTS

Preferred embodiments of the present invention will be described below with reference to the accompanying drawings. Note that the same reference numerals denote the same members throughout the drawings, and a repetitive description thereof will not be given.

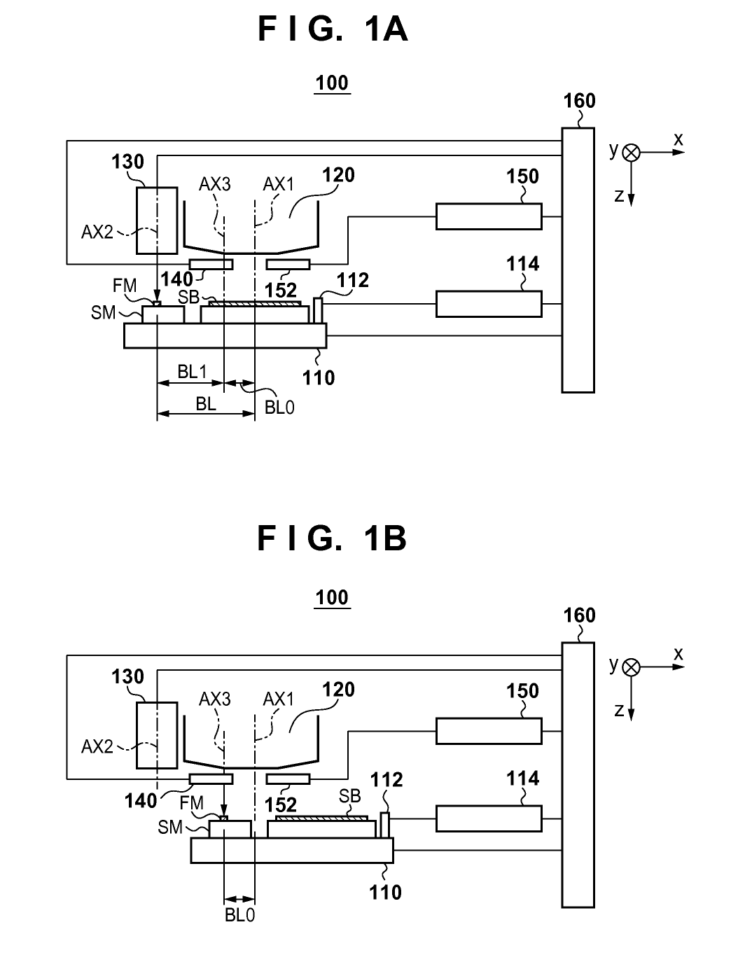

FIGS. 1A and 1B are views showing the arrangement of a drawing apparatus 100 according to one embodiment of the present invention. The drawing apparatus 100 is a lithography apparatus that draws a pattern on a substrate using a charged particle beam (electron beam). The drawing apparatus 100 can be a single-charged particle beam drawing apparatus (drawing apparatus that performs drawing using one charged particle beam) or a multi charged particle beam drawing apparatus (drawing apparatus that performs drawing using a plurality of charged particle beams). The following description will be made assuming that the drawing apparatus 100 is a single-charged particle beam drawing apparatus.

The drawing apparatus 100 includes a substrate stage 110 that moves while holding a substrate SB, a charged particle optical system 120, a first measuring device 130, a second measuring device 140, an obtaining unit 150, and a control unit 160.

As shown in FIGS. 1A and 1B, a reference mark table SM on which a reference mark FM is formed is installed on the substrate stage 110. The reference mark FM is a mark used to position the substrate SB (perform substrate alignment). The position of the substrate stage 110 is measured by a length measuring interferometer 114 including a mirror 112 arranged on the substrate stage 110.

The charged particle optical system 120 includes, for example, a charged particle lens, a collimator lens, an aperture array, a blanker array, a stopping aperture array, and a deflector. The charged particle optical system 120 is accommodated in a housing and emits a charged particle beam from an electron source (not shown) to the substrate SB.

The first measuring device 130 is an off-axis alignment scope arranged at a position different from that of an optical axis (axis) AX1 of the charged particle optical system 120. In this embodiment the first measuring device 130 has an optical axis AX2 spaced apart from the optical axis AX1 of the charged particle optical system 120 by a first distance, and measures the position of an alignment mark formed on the substrate SB. The first measuring device 130 also measures the position of the reference mark FM on the substrate stage 110.

The second measuring device 140 is arranged under the substrate side of the charged particle optical system 120, for example, under the housing that accommodates the charged particle optical system 120. The second measuring device 140 has an optical axis AX3 spaced apart from the optical axis AX1 of the charged particle optical system 120 by a second distance shorter than the first distance, and measures the position of the reference mark FM on the substrate stage 110. In this embodiment, the second measuring device 140 is a scope dedicated for the baseline, which is used to measure the distance between the optical axis AX1 of the charged particle optical system 120 and the optical axis AX2 of the first measuring device 130, that is, the baseline of the first measuring device 130.

In this embodiment, each of the first measuring device 130 and the second measuring device 140 includes an image sensor for sensing the alignment mark or the reference mark FM formed on the substrate SB. An image (image signal) obtained from the image sensor is processed (image processing), thereby measuring the position of the mark. However, the method of measuring the position of the mark FM by the first measuring device 130 and the second measuring device 140 is not limited to a specific one, and any method known by those who are skilled in the art is applicable. For example, the first measuring device 130 and the second measuring device 140 may measure the position of the mark using a position measurement signal obtained by scanning the substrate stage 110.

The obtaining unit 150 obtains the position of the optical axis AX1 of the charged particle optical system 120. In this embodiment, the obtaining unit 150 is implemented as a detection unit that actually detects the position of the optical axis AX1 of the charged particle optical system 120, as will be described later. However, the obtaining unit 150 may be implemented as a storage unit that stores the position of the optical axis AX1 of the charged particle optical system 120 input by the user. The user may input, for example, the optical design value of the charged particle optical system 120 instead of inputting the position of the optical axis AX1 of the charged particle optical system 120. In this case, the obtaining unit 150 is implemented as a simulator that obtains the position of the optical axis AX1 of the charged particle optical system 120 based on the optical design value of the charged particle optical system 120.

The control unit 160 includes a CPU and a memory, and controls the whole (operation) of the drawing apparatus 100. More specifically, the control unit 160 functions as a drawing processing unit that controls drawing processing of performing drawing on the substrate SB using a charged particle beam. The control unit 160 also functions as a measurement processing unit that controls baseline measurement processing of measuring the baseline of the first measuring device 130 (the distance between the optical axis AX1 of the charged particle optical system 120 and the optical axis AX2 of the first measuring device 130). For example, the control unit 160 obtains the baseline of the first measuring device 130 based on the baseline of the second measuring device 140 and the position of the reference mark FM measured by each of the first measuring device 130 and the second measuring device 140 while intervening movement of the substrate stage 110. The baseline of the second measuring device 140 is the distance between the optical axis AX1 of the charged particle optical system 120 and the optical axis AX3 of the second measuring device 140.

Baseline measurement processing in the drawing apparatus 100 will be described. The distance between the optical axis AX1 of the charged particle optical system 120 and the optical axis AX3 of the second measuring device 140, that is, the baseline of the second measuring device 140 is represented by BL0, as shown in FIGS. 1A and 1B. The distance between the optical axis AX1 of the charged particle optical system 120 and the optical axis AX2 of the first measuring device 130, that is, the baseline of the first measuring device 130 is represented by BL.

As shown in FIG. 1A, the substrate stage 110 is moved to locate the reference mark FM in the measurement area of the first measuring device 130. The first measuring device 130 captures the reference mark FM and processes the image, thereby measuring the position of the reference mark FM with respect to the first measuring device 130. At this time, the control unit 160 obtains a position P1 of the substrate stage 110 measured by the length measuring interferometer 114, and stores P1=(X1, Y1) in a memory or the like. Note that the position of the reference mark FM is actually specified based on the measurement result of the first measuring device 130 and that of the length measuring interferometer 114. In this embodiment, however, the position P1 of the substrate stage 110 is equivalent to the position of the reference mark FM measured by the first measuring device 130.

Next, as shown in FIG. 1B, the substrate stage 110 is moved to locate the reference mark FM in the measurement area of the second measuring device 140. The second measuring device 140 captures the reference mark FM and processes the image, thereby measuring the position of the reference mark FM with respect to the second measuring device 140. At this time, the control unit 160 obtains a position P2 of the substrate stage 110 measured by the length measuring interferometer 114, and stores P2=(X2, Y2) in a memory or the like. Note that the position of the reference mark FM is actually specified based on the measurement result of the second measuring device 140 and that of the length measuring interferometer 114. In this embodiment, however, the position P2 of the substrate stage 110 is equivalent to the position of the reference mark FM measured by the second measuring device 140.

The control unit 160 obtains the difference between the position P1 of the substrate stage 110 corresponding to the position of the reference mark FM measured by the first measuring device 130 and the position P2 of the substrate stage 110 corresponding to the position of the reference mark FM measured by the second measuring device 140. The difference between the position P1 and the position P2 of the substrate stage 110 corresponds to a distance BL1 between the optical axis AX2 of the first measuring device 130 and the optical axis AX3 of the second measuring device 140. The control unit 160 also obtains the difference between the position P2 of the substrate stage 110 corresponding to the position of the reference mark FM measured by the second measuring device 140 and the position of the optical axis AX1 of the charged particle optical system 120 obtained by the obtaining unit 150. The difference between the position P2 of the substrate stage 110 and the position of the optical axis AX1 of the charged particle optical system 120 corresponds to the distance BL0 between the optical axis AX1 of the charged particle optical system 120 and the optical axis AX3 of the second measuring device 140. The control unit 160 adds the distance BL0 to the distance BL1, thereby obtaining the baseline BL of the first measuring device 130.

Note that the distance BL0 between the optical axis AX1 of the charged particle optical system 120 and the optical axis AX3 of the second measuring device 140 is set to be much shorter than the baseline BL (the distance between the optical axis AX1 of the charged particle optical system 120 and the optical axis AX2 of the first measuring device 130). More specifically, the second measuring device 140 is arranged close to the optical path of the charged particle beam from the charged particle optical system 120 not to block the optical path, thereby shortening the distance BL0. When the distance BL0 is short, a variation in the baseline BL caused by disturbance such as heat becomes as small as negligible or does not occur at all. In other words, the distance BL0 is supposed not to vary regarding the second measuring device 140. For this reason, the baseline BL can be obtained by adding the distance BL0 to the distance BL1, as described above.

The following condition is also necessary for making the distance BL0 between the optical axis AX1 of the charged particle optical system 120 and the optical axis AX3 of the second measuring device 140 much shorter than the baseline BL. The condition is that the function of the second measuring device 140 is limited to the function of measuring the position of the reference mark FM, thereby causing the second measuring device 140 to have a size (that is, downsizing the second measuring device 140) to enable to arrange it under the charged particle optical system 120.

The first measuring device 130 is configured to be capable of coping with various optical conditions to allow highly accurate measurement of a mark (for example, alignment mark) that has undergone a variety of semiconductor processes. More specifically, the first measuring device 130 has the functions of switching the wavelength of illumination light to illuminate the mark, switching the coherency a of the illumination light, switching the bright field/dark field, and switching to phase difference interferometer detection, thereby increasing the robustness to the semiconductor processes. The optical performance of the first measuring device 130 is required to be λ/10 or less in the transmission wavefront of all systems. To reduce manufacturing errors and the like, the optical systems included in the first measuring device 130, for example, the optical components such as an objective lens and a prism tend to be of a large size. That is, the first measuring device 130 becomes too bulky to implement optical condition switching and high optical performance and cannot be downsized to shorten the baseline BL.

On the other hand, the second measuring device 140 need only measure (the position of) the reference mark FM when obtaining the baseline BL. The reference mark FM is formed by patterning chromium on silica glass, like a reticle (mask). Hence, the optical image of the reference mark FM has an optical contrast of 80% or more, and the second measuring device 140 does not need the robustness of the first measuring device 130 (off-axis alignment scope). As for the optical performance of the second measuring device 140, for example, even if the transmission wavefront is about 2/λ in all systems, only the reference mark FM having the same shape and structure is always measured, and the value of a manufacturing error is constant, posing no problem when obtaining the baseline BL. Hence, the second measuring device 140 can have a small size, and the distance BL0 between the optical axis AX1 of the charged particle optical system 120 and the optical axis AX3 of the second measuring device 140 can be made sufficiently short.

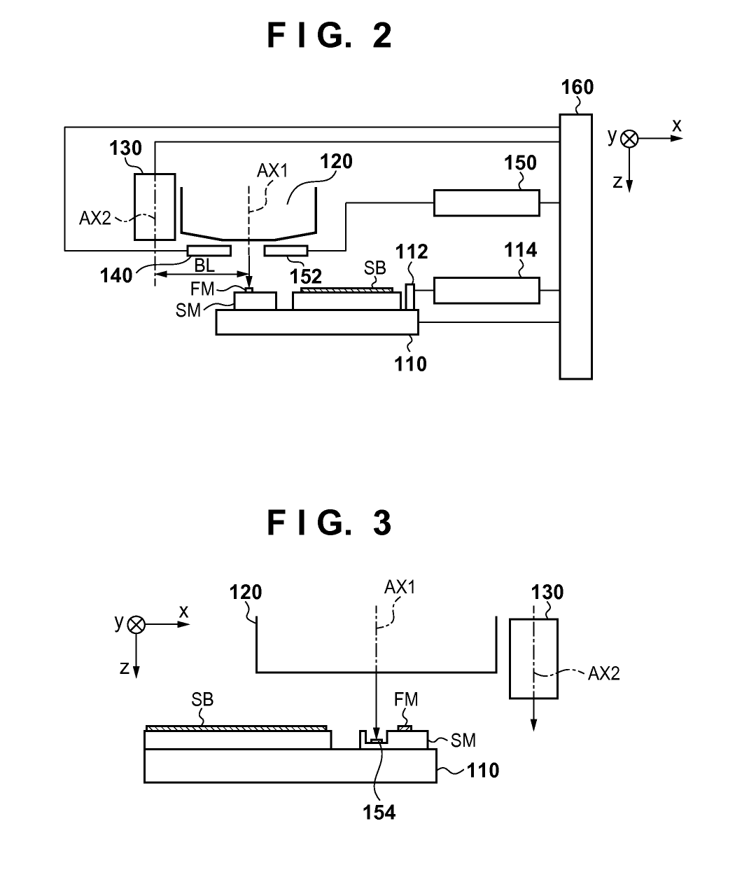

The obtaining unit 150 that obtains the position of the optical axis AX1 of the charged particle optical system 120 will the described with reference to FIG. 2. For example, as shown in FIG. 2, the obtaining unit 150 includes a secondary electron detector (third measuring device) 152 as a detection unit that actually detects the position of the optical axis AX1 of the charged particle optical system 120. The secondary electron detector 152 detects secondary electrons (charged particles) that come flying when the charged particle beam guided to the substrate SB via the charged particle optical system 120 strikes the reference mark FM arranged under the charged particle optical system 120.

Referring to FIG. 2, when detecting the position of the optical axis AX1 of the charged particle optical system 120, the substrate stage 110 is moved to locate the reference mark FM at a position where the charged particle beam from the charged particle optical system 120 strikes. When the charged particle beam strikes the reference mark FM, secondary electrons come flying from the reference mark FM. The secondary electron detector 152 detects the secondary electrons coming flying from the reference mark FM, thereby detecting the strike position of the charged particle beam on the reference mark FM, that is, the position of the optical axis AX1 of the charged particle optical system 120.

As described above, the S/N ratio of the signal (position measurement signal) measured using the charged particle beam is low. To improve the measurement accuracy of the position of the optical axis AX1 of the charged particle optical system 120, the measurement needs to be performed a plurality of times. However, the throughput does not lower because the secondary electron detector 152 measures the position of the optical axis AX1 of the charged particle optical system 120 at a timing at which the drawing apparatus 100 is not operating (that is, when the drawing processing is not being performed).

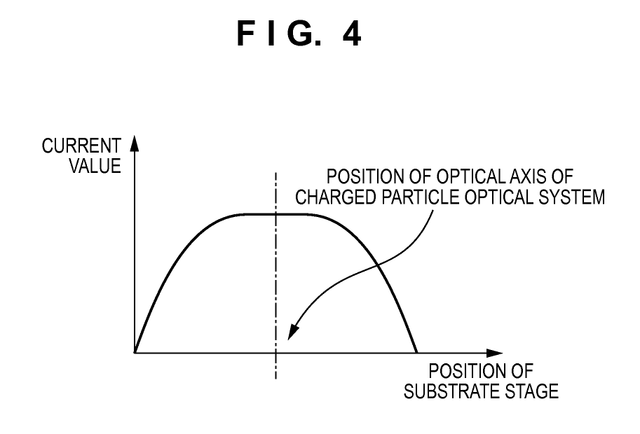

As shown in FIG. 3, the obtaining unit 150 may include a Faraday cup 154 as a detection unit that actually detects the position of the optical axis AX1 of the charged particle optical system 120. The Faraday cup 154 is arranged, for example, near the reference mark FM and detects the charged particle beam guided to the substrate SB via the charged particle optical system 120. At this time, when the substrate stage 110 is moved (that is, the Faraday cup 154 is moved) in the X and Y directions, the Faraday cup 154 can obtain a signal as shown in FIG. 4 and detect the position of the optical axis AX1 of the charged particle optical system 120. Note that the signal as shown in FIG. 4 may be obtained not by moving the substrate stage 110 but by deflecting the charged particle beam. In FIG. 4, the ordinate employs the current value of the charged particle beam detected by the Faraday cup 154, and the abscissa employs the position of the substrate stage 110.

After the substrate alignment is performed using a substrate having a pattern, drawing processing and development processing may be performed, the overlay accuracy may be obtained by an overlay inspection apparatus, and the offset may be reflected on the baseline.

According to the drawing apparatus 100 of this embodiment, it is possible to accurately measure the baseline BL while suppressing the decrease in the throughput (that is, in a short time). Hence, the drawing apparatus 100 can improve the pattern overlay accuracy in the drawing processing of drawing a pattern on the substrate SB using a charged particle beam.

The drawing apparatus 100 may include a plurality of sets each including the first measuring device 130, the second measuring device 140, and the reference mark FM. The plurality of sets are arranged at equal angles about the optical axis AX1 of the charged particle optical system 120. This allows to narrow the moving range of the substrate stage 110.

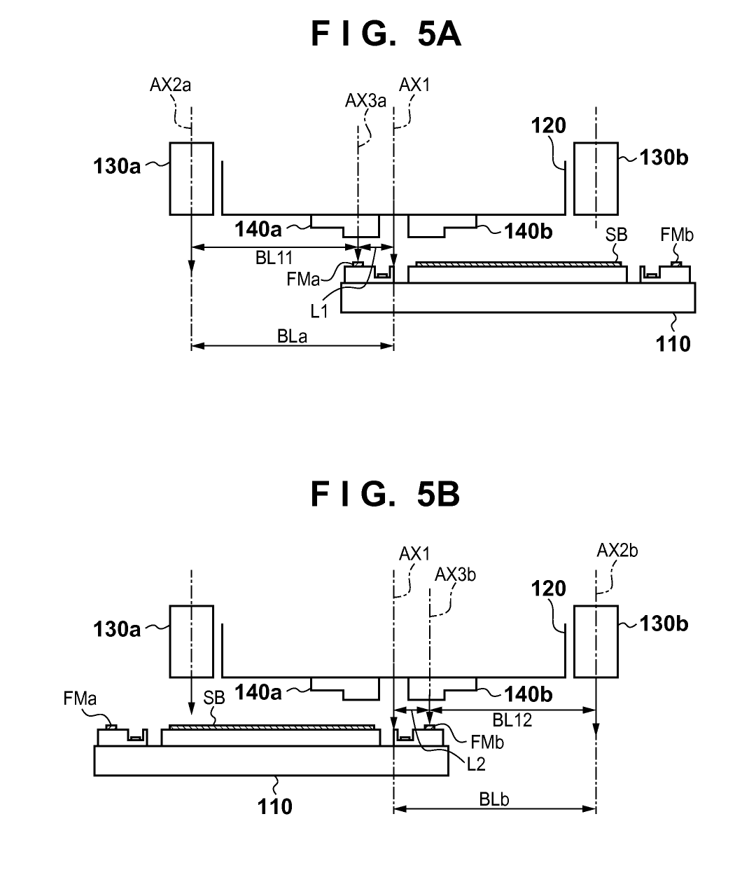

For example, as shown in FIGS. 5A and 5B, the drawing apparatus 100 includes a first set including a first measuring device 130a, a second measuring device 140a, and a reference mark FMa, and a second set including a first measuring device 130b, a second measuring device 140b, and a reference mark FMb.

Referring to FIGS. 5A and 5B, the first measuring devices 130a and 130b are arranged on the left and right sides of (the optical axis AX1 of) the charged particle optical system 120. The second measuring devices 140a and 140b are arranged under the charged particle optical system 120. The reference marks FMa and FMb are arranged on the substrate stage 110.

Baseline measurement processing will be explained. Processing of measuring the distance between the optical axis AX1 of the charged particle optical system 120 and an optical axis AX2a of the first measuring device 130a, that is, a baseline BLa will be described first. As shown in FIG. 5A, the substrate stage 110 is moved to locate the reference mark FMa in the measurement area of the second measuring device 140a, and the second measuring device 140a measures the position of the reference mark FMa. Next, the substrate stage 110 is moved to locate the reference mark FMa in the measurement area of the first measuring device 130a, and the first measuring device 130a measures the position of the reference mark FMa. The difference between the position of the reference mark FMa measured by the second measuring device 140a and the position of the reference mark FMa measured by the first measuring device 130a, that is, a distance BL11 between an optical axis AX3a of the second measuring device 140a and the optical axis AX2a of the first measuring device 130a is thus obtained. A distance L1 between the optical axis AX1 of the charged particle optical system 120 and the optical axis AX3a of the second measuring device 140a is added to the distance BL11, thereby obtaining the distance between the optical axis AX1 of the charged particle optical system 120 and the optical axis AX2a of the first measuring device 130a, that is, the baseline BLa.

Processing of measuring the distance between the optical axis AX1 of the charged particle optical system 120 and an optical axis AX2b of the first measuring device 130b, that is, a baseline BLb will be described next. As shown in FIG. 5B, the substrate stage 110 is moved to locate the reference mark FMb in the measurement area of the second measuring device 140b, and the second measuring device 140b measures the position of the reference mark FMb. Next, the substrate stage 110 is moved to locate the reference mark FMb in the measurement area of the first measuring device 130b, and the first measuring device 130b measures the position of the reference mark FMb. The difference between the position of the reference mark FMb measured by the second measuring device 140b and the position of the reference mark FMb measured by the first measuring device 130b, that is, a distance BL12 between an optical axis AX3b of the second measuring device 140b and the optical axis AX2b of the first measuring device 130b is thus obtained. A distance L2 between the optical axis AX1 of the charged particle optical system 120 and the optical axis AX3b of the second measuring device 140b is added to the distance BL12, thereby obtaining the distance between the optical axis AX1 of the charged particle optical system 120 and the optical axis AX2b of the first measuring device 130b, that is, the baseline BLb.

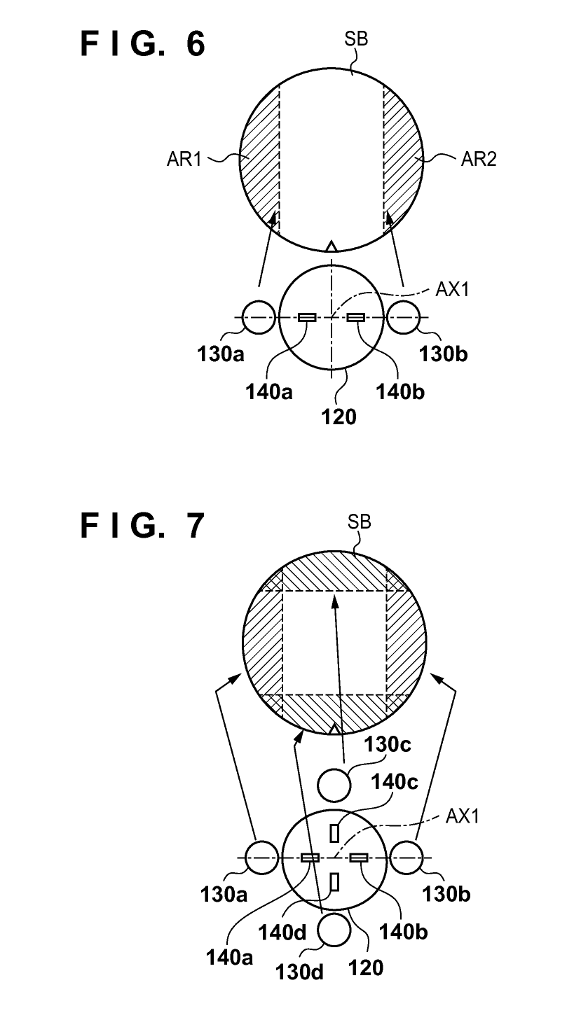

FIG. 6 is a view showing the arrangement relationship between the first measuring devices 130a and 130b and the second measuring devices 140a and 140b in the drawing apparatus 100 shown in FIGS. 5A and 5B. FIG. 6 illustrates a state in which the first measuring devices 130a and 130b and the second measuring devices 140a and 140b are viewed from the direction of the optical axis AX1 of the charged particle optical system 120. AR1 indicates the measurement area of the first measuring device 130a, and AR2 indicates the measurement area of the first measuring device 130b.

As described above, when the drawing apparatus 100 includes a plurality of sets each including the first measuring device 130, the second measuring device 140, and the reference mark FM, the moving range of the substrate stage 110 can be narrowed, contributing to reduction of the apparatus occupation area and reduction of the apparatus cost. In general, the moving accuracy (position accuracy) of the substrate stage 110 tends to be lower as its moving range widens. Hence, narrowing the moving range of the substrate stage 110 also contributes to an increase in moving accuracy of the substrate stage 110.

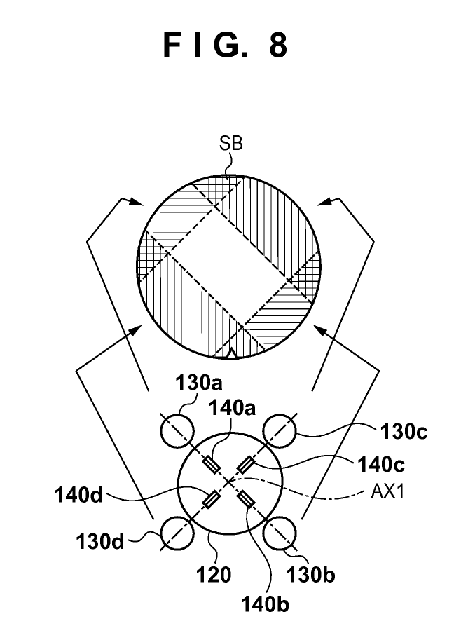

When the drawing apparatus 100 includes four first measuring devices 130a, 130b, 130c, and 130d and four second measuring devices 140a, 140b, 140c, and 140d, as shown in FIG. 7, the moving range of the substrate stage 110 can further be narrowed. Note that in FIG. 7, the four first measuring devices 130a, 130b, 130c, and 130d are arranged on the left, right, upper, and lower sides of the optical axis AX1 of the charged particle optical system 120, respectively. However, the four first measuring devices 130a, 130b, 130c, and 130d may be arranged diagonally at an angle of 45° about the optical axis AX1 of the charged particle optical system 120, as shown in FIG. 8.

When five or more first measuring devices 130 are formed, the second measuring devices 140 and the reference marks FM as many as the first measuring devices are formed. If the moving range of the substrate stage 110 is sufficiently wide, the number of first measuring devices 130 and the number of second measuring devices 140 need not equal. For example, the baselines of a plurality of first measuring devices 130 may be measured using one second measuring device 140.

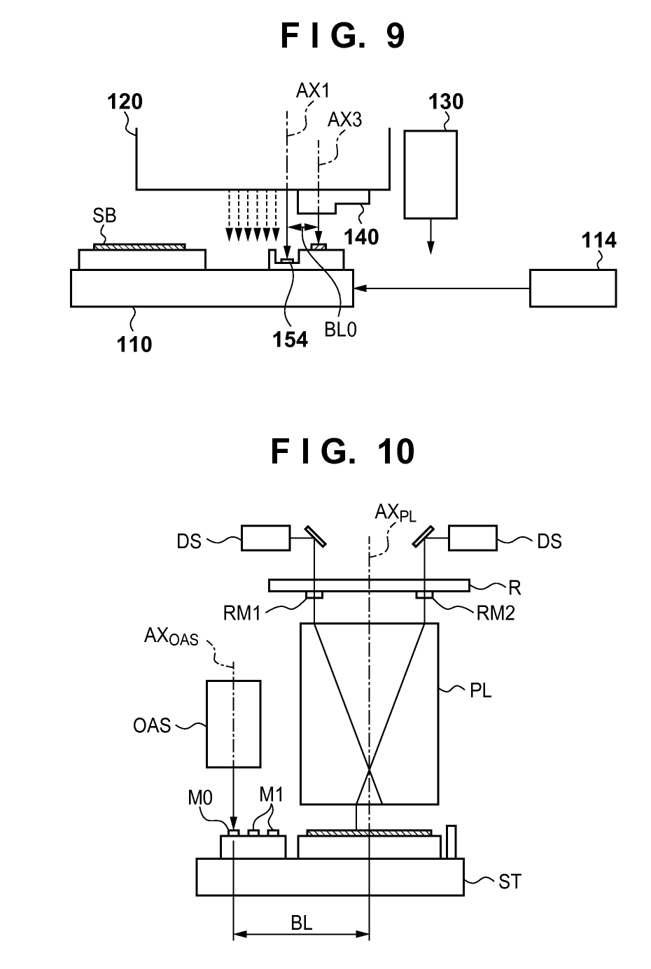

Consider a case in which the drawing apparatus 100 is a multi-charged particle beam drawing apparatus. In this case, the position of the optical axis AX1 of the charged particle optical system 120 is preferably detected using a charged particle beam closest to the optical axis AX3 of the second measuring device 140 out of a plurality of charged particle beams guided to the substrate SB via the charged particle optical system 120, as shown in FIG. 9. This allows to shorten the distance BL0 between the optical axis AX1 of the charged particle optical system 120 and the optical axis AX3 of the second measuring device 140 and so make a generated error small. When the drawing apparatus 100 includes a plurality of second measuring devices 140 (FIGS. 5A to 8), a charged particle beam closest to each of the plurality of second measuring devices 140 is preferably used.

An article manufacturing method according to an embodiment of the present invention is suitable for manufacturing an article, for example, a micro device such as a semiconductor device or an element having a microstructure. The article manufacturing method according to this embodiment includes a step of forming a latent image pattern on a photoresist applied to a substrate using the drawing apparatus 100 (step of performing drawing on a substrate), and a step of developing the substrate on which the latent image pattern has been formed in that step (step of developing the substrate on which the drawing has been performed). This manufacturing method can include other known steps (oxidation, deposition, evaporation, doping, planarization, etching, resist peeling, dicing, bonding, packaging, and the like). The article manufacturing method according to this embodiment is advantageous in at least one of the performance, quality, productivity, and production cost of an article, as compared to a conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent application No. 2011-289888 filed on Dec. 28, 2011, which is hereby incorporated by reference herein in its entirety.

What is claimed is:

1. A drawing apparatus for performing drawing on a substrate with a charged particle beam, comprising:
a stage having a reference mark, and configured to hold the substrate and to be moved;
a charged particle optical system configured to emit the charged particle beam to the substrate;
a first measuring device having an optical axis spaced apart from an axis of the charged particle optical system by a first distance and configured to measure a position of an alignment mark formed on the substrate;
a second measuring device having an optical axis spaced apart from the axis of the charged particle optical system by a second distance shorter than the first distance and configured to measure a position of the reference mark; and
a processor configured to obtain a baseline of the first measuring device based on positions of the reference mark respectively measured by the first measuring device and the second measuring device via movement of the stage, and a baseline of the second measuring device.

2. The apparatus according to claim 1, further comprising a third measuring device configured to detect a charged particle that arrives thereat by causing a charged particle beam to impinge on the reference mark, to measure the position of the reference mark,
wherein the processor is configured to obtain the baseline of the second measuring device based on position of the reference mark respectively measured by the second measuring device and the third measuring device via movement of the stage.

3. The apparatus according to claim 1, further comprising a housing which accommodates the charged particle optical system,
wherein the second measuring device includes a detector arranged under the housing and configured to detect a light from the reference mark.

4. The apparatus according to claim 2, wherein
the drawing apparatus is configured to perform the drawing on the substrate with a plurality of charged particle beams, and
the third measuring device is configured to measure the position of the reference mark with a charged particle beam, of the plurality of charged particle beams, closest to the optical axis of the second measuring device.

5. The apparatus according to claim 1, further comprising a plurality of sets each including the first measuring device, the second measuring device, and the reference mark.

6. A method of manufacturing an article, the method comprising:
performing drawing on a substrate using a drawing apparatus;
developing the substrate on which the drawing has been performed; and
processing the developed substrate to manufacture the article,
wherein the drawing apparatus performs drawing on the substrate with a charged particle beam, the apparatus including
a stage having a reference mark, and configured to hold the substrate and to be moved;
a charged particle optical system configured to emit the charged particle beam to the substrate;
a first measuring device having an optical axis spaced apart from an axis of the charged particle optical system by a first distance and configured to measure a position of an alignment mark formed on the substrate;
a second measuring device having an optical axis spaced apart from the axis of the charged particle optical system by a second distance shorter than the first distance and configured to measure a position of the reference mark; and
a processor configured to obtain a baseline of the first measuring device based on positions of the reference mark respectively measured by the first measuring device and the second measuring device via movement of the stage, and a baseline of the second measuring device.
